(19) United States
(12) Patent Application Publication
(10) Pub. No.: US 2009/0314331 A1
(43) Pub. Date: Dec. 24, 2009

(54) Solar beads

(76) Inventor: Ishitani Toshie, Dewinton (CA)

Correspondence Address: BACON & THOMAS, PLLC, 625 SLATERS LANE, FOURTH FLOOR, ALEXANDRIA, VA, 22314-1176, US

(21) Appl. No.: 12/213,724

(22) Filed: Jun. 24, 2008

(51) Int. Cl. H01L 31/052; G02B 3/00

(52) U.S. Cl. 136/246; 136/259; 359/642

(57) ABSTRACT

This invention relates to solar beads composed of plural solar concentrating units formed granular so as to augment surface area usable for absorbing solar energy. As the solar concentrating units are respectively formed as granules, they are sufficiently flexible after being linked together by conducting lines, not only having a low rate of spoiling but convenient for being partially replaced owing to damage or alteration of module specification.

### BACKGROUND OF THE INVENTION

1. Field of the Invention

This invention relates to solar beads, particularly to those composed of solar concentrating units formed as granules to augment surface area for increasingly absorbing solar energy.

2. Description of the Prior Art

Commonly, a solar panel 1 is applied to generate electricity, based on photoelectric effect. When sunlight shines on a metallic surface of the solar panel 1, its partial photons are to strike the metallic atoms to generate energy, part of which is converted to upgrade potential energy of the outer electrons of the metallic atoms to make them freed from the atoms, and part of which is converted into dynamic energy to benefit electrons to move off atoms. As the freed electrons are electrically negative, they form a negative voltage in a conductor so as to flow to a region with a relatively higher potential (a less negative value), becoming electric energy for human being to use after being properly adjusted. The conventional solar panel 1 is usually made of a crystal and a non-crystal panel. The non-crystal panel is composed of a piece of glass coated with two layers of semi-conducting material, one being an N-type semi-conducting layer and the other being a P-type one, respectively connected with a conducting line. The crystal panel can convert solar energy into electric energy 100% more than the non-crystal can while exposed to blazing sunlight, but it has a costly price as high as three to four times of the non-crystal one. On the contrary, under a cloudy condition, the non-crystal panel can collect more solar energy than the crystal panel can. However, the surface of the conventional solar panel 1 is made of a flat glass that is fragile and apt to be damaged or even broken entirely in case of being hit. Moreover, it still has a high price and has to be positioned immovably because it is inflexible.

### SUMMARY OF THE INVENTION

The object of this invention is to offer solar beads.

The main characteristics of the invention are solar concentrating units formed granular so as to augment surface area for increasingly absorbing solar energy, not only having a low rate of spoiling but convenient for being partially refreshed owing to damage or alteration of module specification.

### BRIEF DESCRIPTION OF DRAWINGS

This invention is better understood by referring to the accompanying drawings, wherein:

FIG. 1 is a perspective view of a conventional solar panel;

FIG. 2 is a perspective view of a first preferred embodiment of solar beads in the present invention, showing its solar concentrating units formed as round granules and linked together in series;

FIG. 3 is a top view of the first preferred embodiment of solar beads in the present invention, showing its solar concentrating units linked together in series;

FIG. 4 is a loop circuit of the first preferred embodiment of solar beads in the present invention;

FIG. 5 is a cross-sectional view of each of the solar concentrating units of the first preferred embodiment of solar beads in the present invention;

FIG. 6 is a top view of a second preferred embodiment of solar beads in the present invention, showing its solar concentrating units formed as elliptic granules and linked together in series;

FIG. 7 is a perspective view of the second preferred embodiment of solar beads in the present invention, showing its solar concentrating units linked together in series;

FIG. 8 is a top view of a third preferred embodiment of solar beads in the present invention, showing its solar concentrating units formed as square granules and linked together in series;

FIG. 9 is a perspective view of the third preferred embodiment of solar beads in the present invention, showing its solar concentrating units linked together in series;

FIG. 10 is a top view of a fourth preferred embodiment of solar beads in the present invention, showing its solar concentrating units formed as diverse shapes of granules and linked together in series; and

FIG. 11 is a perspective view of the fourth preferred embodiment of solar beads in the present invention, showing its solar concentrating units linked together in series.

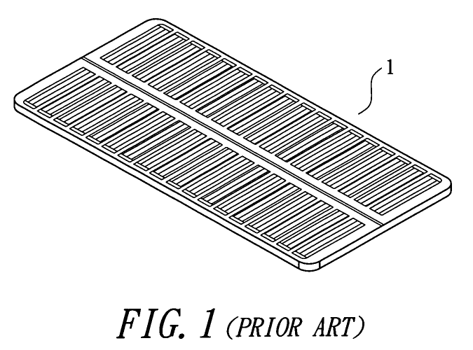

### DETAILED DESCRIPTION OF THE PREFERRED EMBODIMENT

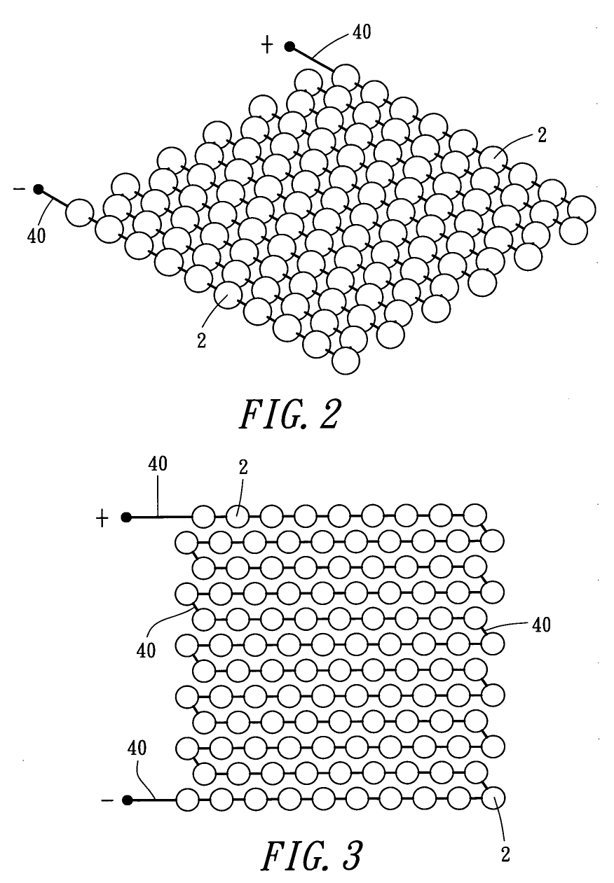

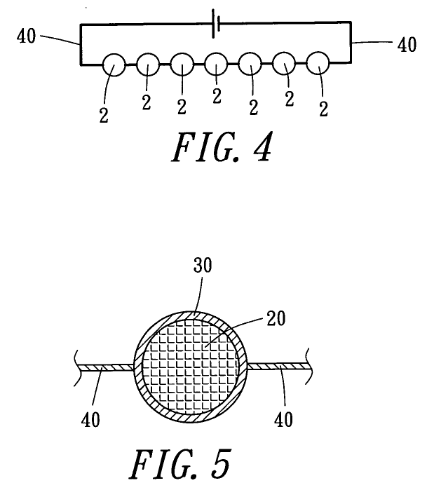

As shown in FIGS. 2˜5, a first preferred embodiment of solar beads in the present invention is composed of a plurality of solar concentrating units 2, which are respectively formed round, provided with a semiconductor 20 formed as their inner layer and an outer silicon layer 30 wrapped around the semiconductor 20. Plural conducting lines 40 (such as wires) are connected between every two of the solar concentrating units 2 in series, enabling the solar concentrating units 2 formed as a loop. By means of the semiconductor 20, solar energy can be converted into electric energy as the solar concentrating units 2 are illuminated by sunlight. If the solar concentrating units 2 are damaged or to be replaced with new ones owing to alteration of specification, only those damaged or necessary to be replaced with new ones of other specification have to be replaced, unnecessary to be entirely replaced. In addition, the solar concentrating units 2 are convenient for being carried about no matter whether they are kept individually or linked together. And, with the solar concentrating units 2 formed as a ball, a lot of surfaces can be used so that electric energy can largely be increased.

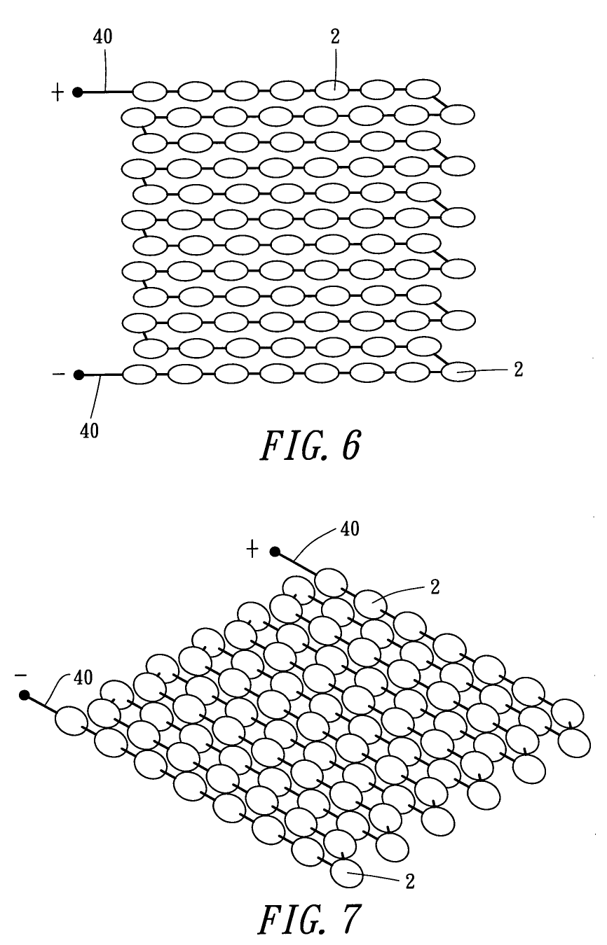

As shown in FIGS. 6 and 7, a second preferred embodiment of solar beads in the present invention has the solar concentrating units 2 formed elliptic based on the same technical theory and the structural principle.

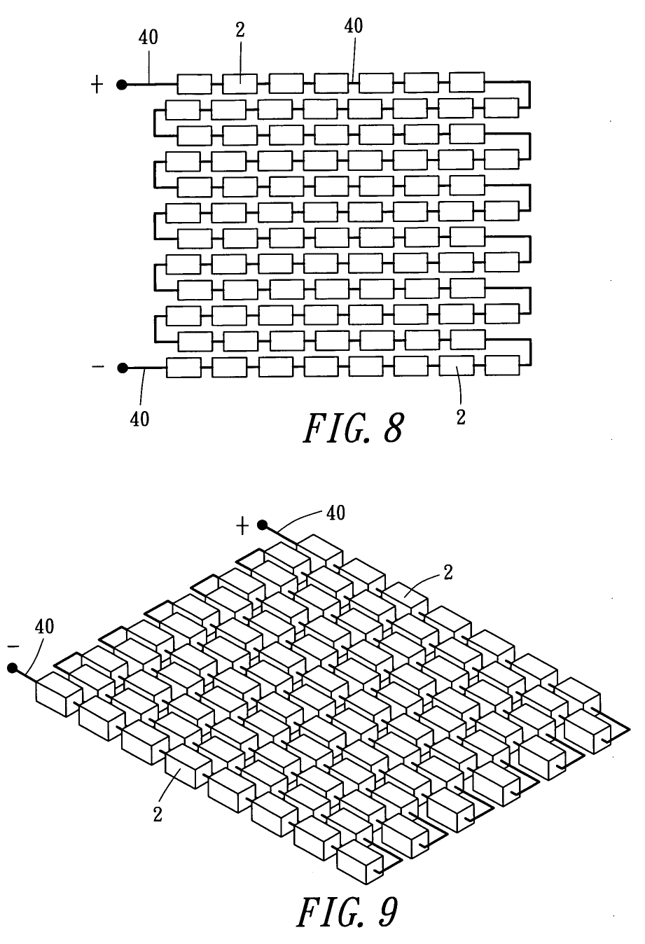

As shown in FIGS. 8 and 9, a third preferred embodiment of solar beads in the present invention has the solar concentrating units 2 formed square based on the same way as mentioned above.

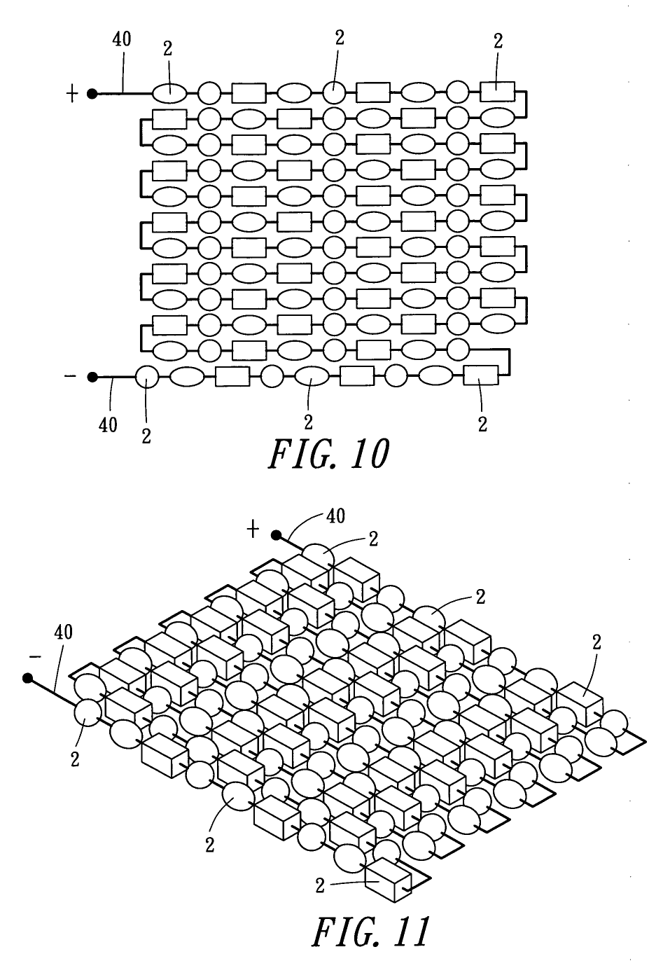

Finally, as shown in FIGS. 10 and 11, a fourth preferred embodiment of solar beads in the present invention has the solar concentrating units 2 formed round, elliptic and square based on the same way mentioned above.

The advantages of the invention are described as can be seen from the foresaid description.

With the solar concentrating units 2 formed granular, a lot of surface area can be used for absorbing solar energy. By means of the semiconductor 20, solar energy is converted into electric energy for use. In case that the solar concentrating units 2 are damaged or to be replaced with new ones owing to specification changes, only those damaged or necessary to be replaced with new ones of different specification have to be replaced, instead of being entirely changed. The solar concentrating units 2 are convenient for being carried about no matter whether they are kept individually or linked together, so that they can be positioned at anywhere like a curtain, a carport, an umbrella, a hat, clothes or a tent, etc. and a house roof as well.

While the preferred embodiment of the invention has been described above, it will be recognized and understood that various modifications may be made therein and the appended claims are intended to cover all such modifications that may fall within the spirit and scope of the invention.

What is claimed is:

1. Solar beads comprising a plurality of solar concentrating units formed granular so as to multiply surface area usable for absorbing solar energy.

2. The solar beads as claimed in claim 1, wherein each of said solar concentrating units is provided with a semiconductor formed as its inner layer and a silicon layer wrapped around said semi conductor.

3. The solar beads as claimed in claim 1, wherein said solar concentrating units are linked together in series by conducting lines to become a loop.

4. The solar beads as claimed in claim 1, wherein said solar concentrating units are respectively formed as round granules.

5. The solar beads as claimed in claim 1, wherein said solar concentrating units are respectively formed as elliptic granules.

6. The solar beads as claimed in claim 1, wherein said solar concentrating units are respectively formed as square granules.
